(19) United States
(12) Patent Application Publication
(10) Pub. No.: US 2025/0244367 A1
(43) Pub. Date: Jul. 31, 2025

(54) METHOD AND SYSTEM FOR TRACKING A SAMPLE OF INTEREST IN A SIGNAL PROCESSING DEVICE

(71) Applicant: Keysight Technologies, Inc., Santa Rosa, CA (US)

(72) Inventors: Ryan Pearson, Colorado Springs, CO (US); Devon Fossceco, Colorado Springs, CO (US); Caleb Begly, Colorado Springs, CO (US); Scott Allan Genther, Colorado Springs, CO (US); Joseph Shaker, Colorado Springs, CO (US)

(21) Appl. No.: 18/428,415

(22) Filed: Jan. 31, 2024

(51) Int. Cl. G01R 19/25; G01R 23/16

(52) U.S. Cl. CPC G01R 19/2506; G01R 23/16

(57) ABSTRACT

A method and system for tracking a sample of interest in a signal processing device are disclosed. The method involves receiving a plurality of samples in an input data pipe, marking a specific sample within the input data pipe as a sample of interest, and processing the plurality of samples through a decimation circuit. The marked sample is tracked through the decimation circuit to determine a mark position within the reduced set of samples in the output data pipe. The mark position is outputted as metadata associated with the reduced set of samples. The marked sample is tracked such that a resolution of the mark position in the output data pipe is the same as a resolution of the mark position in the input data pipe.

### FIELD

The present disclosure generally relates to methods and systems for tracking a sample of interest in a signal processing device, specifically in the context of decimation circuits within digital storage oscilloscopes and spectrum analyzers.

### BACKGROUND

Digital storage oscilloscopes (DSOs) and spectrum analyzers are widely used in various fields such as electronics, telecommunications, and signal processing. These devices are designed to capture, process, and display waveform signals in a digital format. They convert the analog signals into digital form using an analog-to-digital converter (ADC), and then process the digitized signals to extract useful information.

One of the primary functions of these devices is to measure and analyze the amplitude, frequency, and phase of the input signals. To achieve this, the input signals are often subjected to various signal processing operations such as mixing, filtering, decimation, and compression. These operations obtain processing gain, improve the frequency resolution of fixed length FFTs, and allow for some I/Q analysis, as well as help to reduce the amount of data that has to be processed and stored, thereby improving the efficiency and performance of the device.

Decimation is a common signal processing technique used in DSOs and spectrum analyzers. It involves reducing the number of samples in a signal by a specific factor, known as the decimation factor. This is typically achieved by discarding some of the samples and keeping others. The decimation process can be performed in several stages. In some examples, each stage reduces the number of samples by a factor of two. This is often referred to as decimate-by-two operation.

While decimation is a useful technique for reducing the amount of data, it can also introduce challenges in tracking specific samples of interest through the signal processing chain. For instance, when a specific sample is marked as a sample of interest at the input, it may be difficult to track its position after the decimation process. This is because the decimation process can change the position of the marked sample within the data pipe, making it challenging to accurately track and identify the marked sample at the output. In addition, the sample that was marked could be decimated away.

### SUMMARY

In general, in a first aspect, a method is provided that features tracking a sample of interest in a signal processing device. This involves receiving a plurality of samples in an input data pipe, which comprises a predetermined number of samples to be processed each clock cycle. A specific sample within the input data pipe is marked as a sample of interest, the specific sample having a mark position within the input data pipe. The plurality of samples are processed through a decimation circuit, which is configured to output a reduced set of samples in an output data pipe. The marked sample is tracked through the decimation circuit to determine a mark position within the reduced set of samples in the output data pipe. The mark position is outputted as metadata associated with the reduced set of samples. The marked sample is tracked through the decimation circuit such that a resolution of the mark position in the output data pipe is the same as a resolution of the mark position in the input data pipe.

Embodiments of the method may include one or more of the following features. The decimation circuit may comprise a plurality of cascaded decimate-by-two stages. The decimation circuit may be configured to process multiple samples per clock cycle. The marked sample may be used for triggering in an oscilloscope application or for phase correction in a spectrum analyzer application. The method may further comprise using the mark position to align a trigger when plotting data or to correct a phase offset introduced during signal acquisition. The mark position may be used to determine the location of the marked sample within the reduced set of samples output from the decimation circuit. The mark position may be used to facilitate data compression operations of the signal processing device or to facilitate plotting operations of the signal processing device.

In another aspect, a signal processing device is provided that is configured to implement the method. The device may be an oscilloscope or a spectrum analyzer. The device may comprise an Application-Specific Integrated Circuit (ASIC) configured to implement the method. The ASIC may be configured to process multiple samples per clock cycle through a decimation circuit.

### BRIEF DESCRIPTION OF THE DRAWINGS

The above and other aspects and features of the inventive concepts will become readily apparent from the detailed description that follows, with reference to the accompanying drawings, in which:

FIG. 1 is a block diagram of an exemplary digital storage oscilloscope (DSO);

FIG. 2 is a circuit diagram illustrating an example of the analog input signal conditioning circuit shown in FIG. 1;

FIG. 3 is a circuit diagram for reference in describing the ADC and the trigger block shown in FIG. 1;

FIG. 4 is a circuit diagram for reference in describing examples of the acquisition memory and the timebase system shown in FIG. 1;

FIG. 5 is a block diagram for reference in describing the DSP display block of FIG. 1;

FIG. 6 is a block diagram of an oscilloscope signal acquisition and processing system;

FIG. 7 is a block diagram of an exemplary spectrum analyzer;

FIG. 8 is a block diagram of a decimation circuit for down-sampling the output of the ADC;

FIG. 9 is a flowchart for reference in describing the position marking of a sample of interest as it propagates through a decimation circuit; and

FIGS. 10 through 12 are diagrams for reference in describing examples of different marking and decimation scenarios.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted to avoid obscuring the description of the example embodiments. Such methods and apparatuses are clearly within the scope of the present teachings. Further, throughout the drawings, like reference numbers refer to the same or similar elements.

The terminology used herein is for purposes of describing particular embodiments only, and is not intended to be limiting. The defined terms are in addition to the technical and scientific meanings of the defined terms as commonly understood and accepted in the technical field of the present teachings. As used in the specification and appended claims, the terms ‘a’, ‘an’ and ‘the’ include both singular and plural referents, unless the context clearly dictates otherwise. Thus, for example, ‘a device’ includes one device and plural devices. Further, for example, when one element is described as being “connected to” another element, the one element may be directly connected to the other element, or indirectly connected to the other element in an operative manner.

Separately, as is traditional in the field of the inventive concepts, example embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, in the absence of an indication to the contrary, the units and/or modules being implemented by microprocessors or similar may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the example embodiments may be physically separated into two or more interacting and discrete blocks, units and/or modules without departing from the scope of the example embodiments. Conversely, the blocks, units and/or modules of the example embodiments may be physically combined into more complex blocks, units and/or modules without departing from the scope of the example embodiments.

The method for tracking a sample of interest in a signal processing device begins with receiving a plurality of samples in an input data pipe. The input data pipe comprises a predetermined number of samples. A specific sample within the input data pipe is marked as a sample of interest. The specific sample has a mark position within the input data pipe. This mark position is a reference point that is used to track the sample of interest as it moves through the signal processing device.

The plurality of samples are then processed through a decimation circuit. The decimation circuit is configured to output a reduced set of samples in an output data pipe. The decimation circuit can be a simple decimation circuit or a more complex one that includes, for example, a plurality of cascaded decimate-by-two stages. The decimation circuit can also be configured to process multiple samples per clock cycle, which allows for processing sample rates higher than the clock rate of the DSP chip.

The marked sample is tracked through the decimation circuit to determine a mark position within the reduced set of samples in the output data pipe. The tracking of the marked sample involves keeping track of the position of the marked sample as it moves through the decimation circuit. This is done by associating the marked sample with a mark position within the output data pipe. The mark position is a reference point that indicates the location of the marked sample within the output data pipe.

Finally, the mark position is outputted as metadata associated with the reduced set of samples. The metadata provides information about the location of the marked sample within the output data pipe. This information can be used for various purposes, such as aligning a trigger when plotting data, correcting a phase offset introduced during signal acquisition, facilitating data compression operations of the signal processing device, or facilitating plotting operations of the signal processing device.

Importantly, the marked sample is tracked through the decimation circuit such that a resolution of the mark position in the output data pipe is the same as a resolution of the mark position in the input data pipe. This ensures that the marked sample can be accurately tracked and located within the output data pipe, regardless of the decimation process.

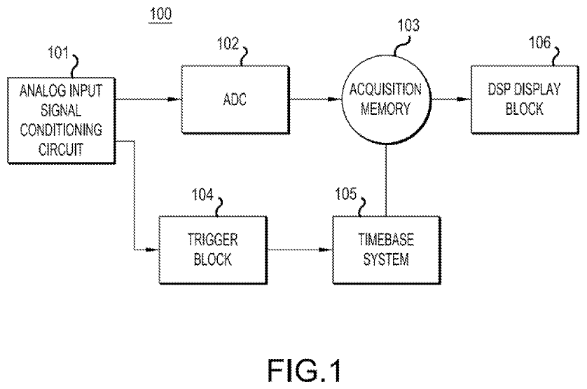

Prior to discussing in detail further aspects of the inventive concepts, as background a digital oscilloscope and spectrum analyzer will be described with reference to FIGS. 1-7.

Referring to FIG. 1, a digital storage oscilloscope (DSO) 100 is depicted. The DSO 100 is a type of signal processing device that is used to capture, process, and display waveform signals in a digital format. The DSO 100 includes various components that are interconnected to illustrate the path taken by an analog signal from input to display.

The analog signal first enters the DSO 100 through an analog input signal conditioning circuit 101. The analog input signal conditioning circuit 101 is configured to condition the analog signal before it is processed by the DSO 100. This may involve adjusting the amplitude, offset, frequency content, or phase of the analog signal to ensure that it is within the acceptable range for the DSO 100.

After being conditioned, the analog signal is then fed into an analog-to-digital converter (ADC) 102. The ADC 102 is responsible for converting the analog signal into a digital format. This involves sampling the analog signal at regular intervals and quantizing each sample to produce a digital representation of the analog signal.

The digitized signal is then stored in an acquisition memory 103. The acquisition memory 103 serves as a temporary storage area for the digitized signal. It allows the DSO 100 to store the digitized signal for later processing and analysis.

Simultaneously, the signal is also passed to a trigger block 104. The trigger block 104 interacts with a timebase system 105 to coordinate the timing of the signal processing operations performed by the DSO 100. The trigger block 104 can be configured to generate a trigger signal based on a specific event or condition in the signal. This trigger signal can then be used to synchronize the processing of the digitized signal with other operations of the DSO 100.

Finally, the processed digitized signal is sent to a digital signal processor (DSP) display block 106 for visualization. The DSP display block 106 is responsible for generating a visual representation of the digitized signal. This visual representation can be displayed on a monitor or other display device, allowing users to analyze the characteristics of the digitized signal.

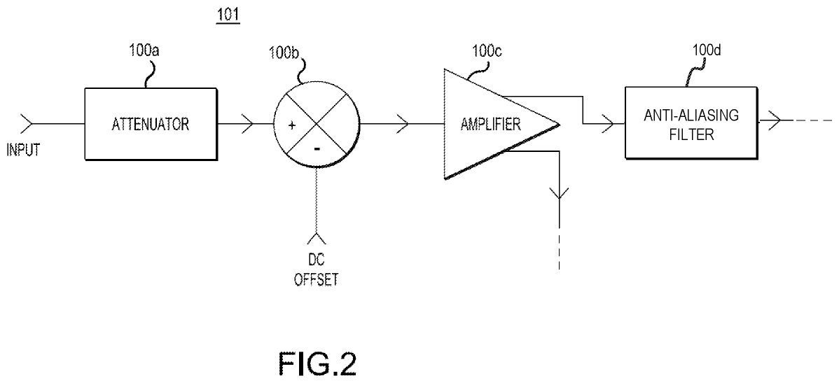

Referring to FIG. 2, an example of the analog input signal conditioning circuit 101 of FIG. 1 is illustrated. In this example, the analog input signal conditioning circuit 101 includes an attenuator 100a, a DC offset 100b, an amplifier 100c, and an anti-aliasing filter 100d. The attenuator 100a is used to reduce the amplitude of the incoming signal to a level that can be handled by the subsequent stages of the DSO 100. The DC offset 100b is used to shift the signal up or down in voltage, which can be useful for centering the signal around a particular voltage level. The amplifier 100c is used to increase the amplitude of the signal, which can be useful for boosting weak signals to a level that can be effectively processed by the DSO 100. The anti-aliasing filter 100d is a lowpass filter utilized to ensure the signal is bandlimited prior to sampling.

In some cases, the analog input signal conditioning circuit 101 may be configured to perform additional signal processing operations, such as filtering or modulation. These additional operations can be used to further condition the analog signal, enhancing the performance and functionality of the DSO 100.

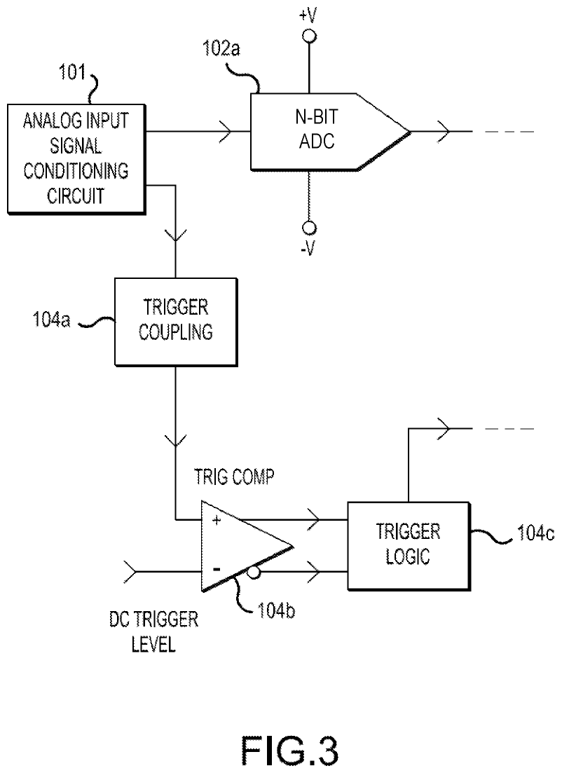

Referring to FIG. 3, a circuit diagram is provided to describe the analog-to-digital converter (ADC) 102 and the trigger block 104 shown in FIG. 1. As previously mentioned, the ADC 102 is responsible for converting the analog signal into a digital format. This conversion process involves sampling the analog signal at regular intervals and quantizing each sample to produce a digital representation of the analog signal. In this example, the ADC 102 is an N-bit analog-to-digital converter, which means it can represent the analog signal with a resolution of 2^{N} distinct levels.

The trigger block 104 of the illustrated example includes a trigger coupling 104a, a trigger comparator 104b, and a trigger logic 104c. The trigger coupling 104a is used to access the analog input signal. The trigger comparator 104b is used to compare the input signal with a reference signal to determine when a trigger event has occurred. The trigger logic 104c is used to generate the trigger signal based on the output of the trigger comparator 104b.

In some cases, the mark position may be used to align data when plotting triggered data from multiple sources. This involves using the mark position as a reference point in calculations to determine when to start plotting the data. This can be useful for aligning the data with other signals or events, or for synchronizing the data with the operation of other components of the DSO 100.

In other cases, the mark position may be used to determine the location of the marked sample within the reduced set of samples output from the decimation circuit. This involves using the mark position as a reference point to identify the marked sample within the output data pipe. This can be useful for tracking the marked sample as it moves through the DSO 100, or for identifying the marked sample for further processing or analysis.

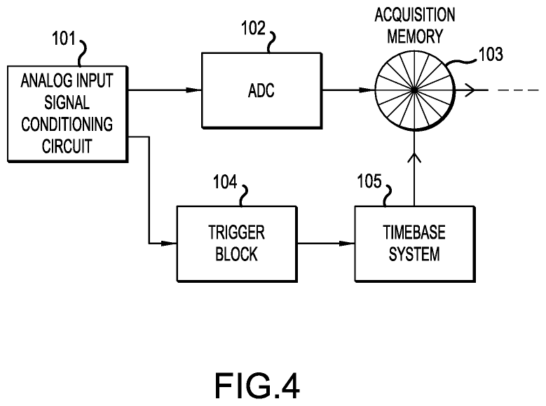

Referring to FIG. 4, a block diagram is provided to describe examples of the acquisition memory 103 and the timebase system 105. As previously mentioned, the acquisition memory 103 is a component of the digital storage oscilloscope (DSO) 100, which serves as a temporary storage area for the digitized signal. The acquisition memory 103 allows the DSO 100 to store the digitized signal for later processing and analysis. The size of the acquisition memory 103 can vary depending on the specific requirements of the DSO 100. In some cases, the acquisition memory 103 may be large enough to store a large number of samples, allowing for more detailed analysis of the signal. In other cases, the acquisition memory 103 may be smaller, allowing for faster processing of the signal.

The timebase system 105 is another component of the DSO 100, which interacts with the trigger block 104 to coordinate the timing of the signal processing operations performed by the DSO 100. The timebase system 105 can be configured to generate a timing signal based on a specific event or condition in the digitized signal. This timing signal can then be used to synchronize the processing of the digitized signal with other operations of the DSO 100. The timebase system 105 may also be configured to adjust a decimation process such that a lower sampling rate is stored.

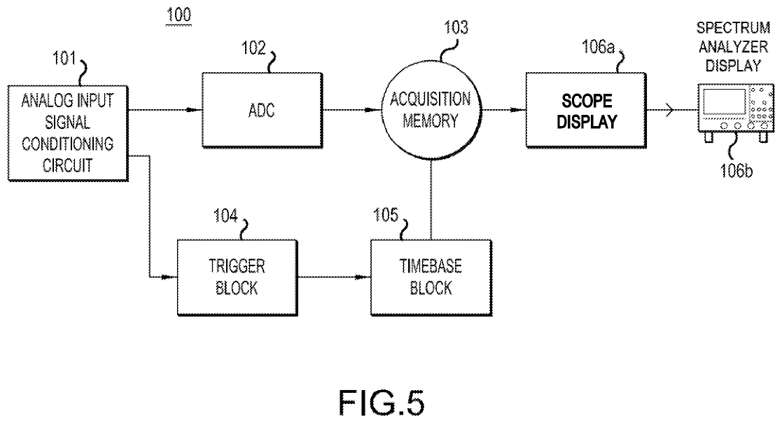

FIG. 5 is a block diagram for reference in describing the digital signal processor (DSP) display block 106 of the digital storage oscilloscope (DSO) 100. The DSP display block 106 is responsible for generating a visual representation of the digitized signal. This visual representation can be displayed on a monitor or other display device, allowing users to analyze the characteristics of the digitized signal.

The DSP display block 106 includes a display 106b and a display digital signal processor (DSP) 106a. The display 106b is the interface through which the visual representation of the digitized signal is presented to the user. The display digital signal processor (DSP) 106a is responsible for processing the digitized signal and generating the visual representation that is displayed on the display 106b.

The DSP display block 106 interacts with the timebase system 105, the acquisition memory 103, the analog-to-digital converter (ADC) 102, the analog input signal conditioning circuit 101, and the trigger block 104. The timebase system 105 coordinates the timing of the signal processing operations performed by the DSO 100. The acquisition memory 103 serves as a temporary storage area for the digitized signal. The ADC 102 converts the analog signal into a digital format. The analog input signal conditioning circuit 101 conditions the analog signal before it is processed by the DSO 100. The trigger block 104 generates a trigger signal based on a specific event or condition in the digitized signal.

In some cases, the mark position may be used to facilitate plotting operations of the signal processing device. This involves using the mark position as a point in calculations to determine when to start plotting the data. This can be useful for aligning the data with other signals or events, or for synchronizing the data with the operation of other components of the DSO 100. For example, the mark position can be used to align data when plotting triggered data from multiple sources, or to correct a phase offset introduced during signal acquisition.

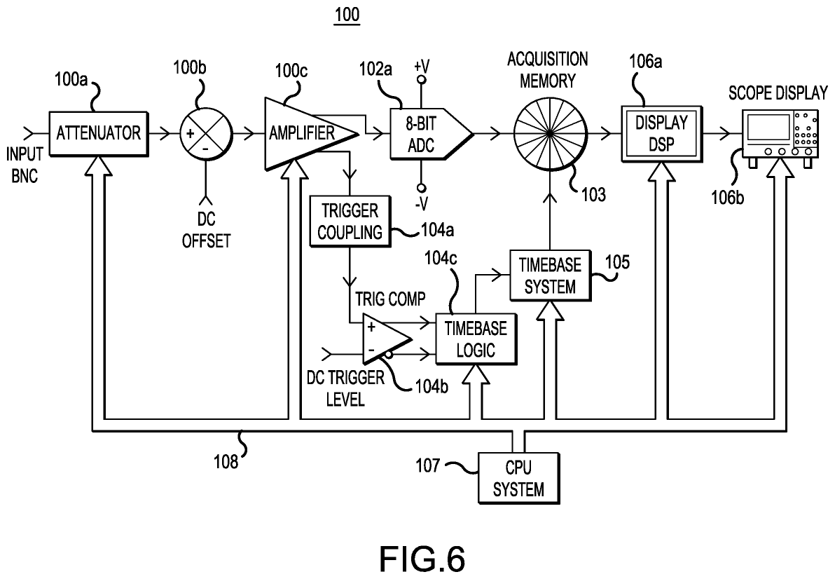

FIG. 6 is an overall block diagram of the digital storage oscilloscope 100 including the components described above in connection with FIGS. 2-5. In addition, FIG. 6 depicts a CPU system 107 which coordinates and directs operations of the various components, as well as a bus system 108 over which the various components may communicate with one another.

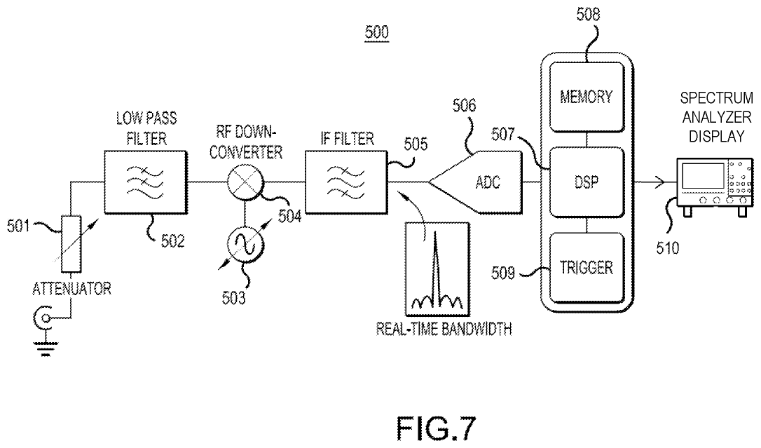

Referring to FIG. 7, a block diagram illustrating an exemplary spectrum analyzer 500. As shown, the spectrum analyzer 500 includes an attenuator 501 that receives an input signal. The attenuator 501 is used to reduce the amplitude of the incoming signal to a level that can be handled by the subsequent stages of the spectrum analyzer. The attenuated signal is then fed into a low pass filter 502. The low pass filter 502 is used to remove high frequency components from the signal, thereby smoothing out the signal and reducing noise.

After being filtered, the signal is then passed to a mixer 504. The mixer 504 also receives a signal from a local oscillator (LO) 503. The LO 503 generates a signal with a constant frequency that is used to mix with the filtered signal. The mixed signal is then processed by a frequency mixer 504. The frequency mixer 504 combines the filtered signal and the signal from the LO 503 to produce a mixed signal with an intermediate frequency that is the difference in the frequencies of the two input signals.

The mixed signal is then passed through an intermediate frequency (IF) filter 505. The IF filter 505 is used to further filter the mixed signal, removing unwanted frequency components and leaving a desired frequency band. The filtered mixed signal is then converted into a digital format by an analog-to-digital converter (ADC) 506. The ADC 506 samples the filtered mixed signal at regular intervals and quantizes each sample to produce a digital representation of the signal.

The digitized signal is then processed by a digital signal processor (DSP) 507. The DSP 507 performs various signal processing operations on the digitized signal, such as filtering, decimation, and compression. The processed digitized signal is then stored in an acquisition memory 508 for later retrieval and analysis.

The signal processing device also includes trigger circuits 509 that generate a trigger signal based on a specific event or condition in the digitized signal. This trigger signal can be used to synchronize the processing of the digitized signal with other operations of the signal processing device. For example, the trigger signal can be used correct a phase offset introduced during signal acquisition.

The processed digitized signal is then displayed in various formats on a spectrum analyzer display 510. These formats may include, as examples, a frequency domain view and a spectrogram view Each of these views provides a different perspective on the signal, allowing users to analyze the signal in various ways.

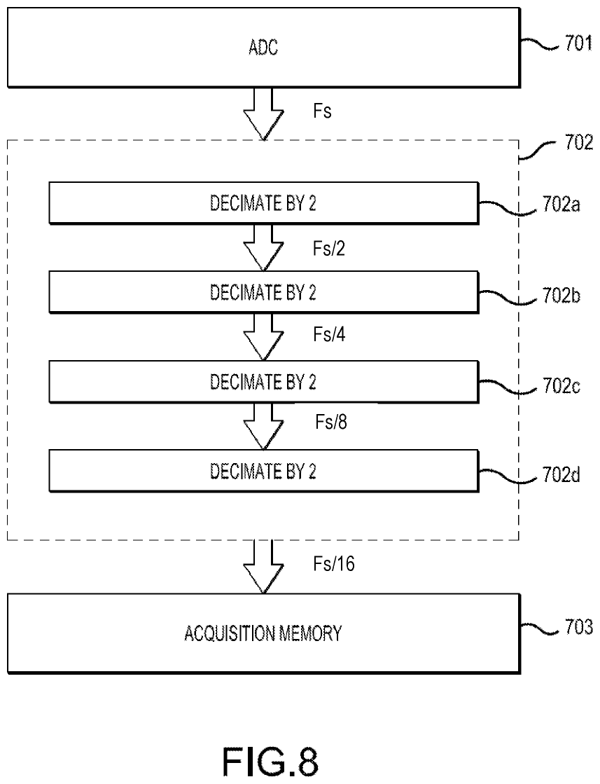

Referring to FIG. 8, a block diagram of a decimation circuit 702 for down-sampling the output of an analog-to-digital converter (ADC) 701 is depicted. As examples, the ADC 701 of FIG. 8 may be the ADC 102 of the digital oscilloscope 100 of FIG. 1, or the ADC 506 of the spectrum analyzer 500 of FIG. 7. The decimation circuit 702 is operatively interposed between the output of the ADC 701 and the input of an acquisition memory 703. The decimation circuit 702 is configured to reduce the number of samples in the output of the ADC 701 by a specific factor, known as the decimation factor. This is typically achieved by discarding some of the samples and keeping others.

In the illustrated example, the decimation circuit 702 includes four decimate-by-two stages 702a, 702b, 702c, and 702d. Each decimate-by-two stage is configured to divide the number of samples per second (Sa/s) by 2. This means that for each stage, the number of samples in the output is half the number of samples in the input. The decimation process can be performed in several stages, each stage reducing the number of samples by a factor of two. This is often referred to as a decimate-by-two operation.

In the example of FIG. 8 having four (4) decimate-by-2 stages, assuming the output samples per second of the ADC 701 is Fs, a sample rate of Fs/16 is applied to the acquisition memory 703. This effectively reduces the amount of data that has to be processed and stored, thereby improving the efficiency and performance of the signal processing device.

In some cases, the decimation circuit 702 may be configured to process multiple samples per clock cycle. This allows for more efficient processing of the samples, as multiple samples can be processed simultaneously within a single clock cycle. This can be particularly beneficial in applications where high-speed signal processing is desired.

In other cases, the decimation circuit 702 may comprise a plurality of cascaded decimate-by-two stages. This configuration allows for a more flexible and scalable decimation process, as the number of stages can be adjusted to achieve the desired decimation factor. This can be particularly useful in applications where different decimation factors may be desired for different signal processing tasks.

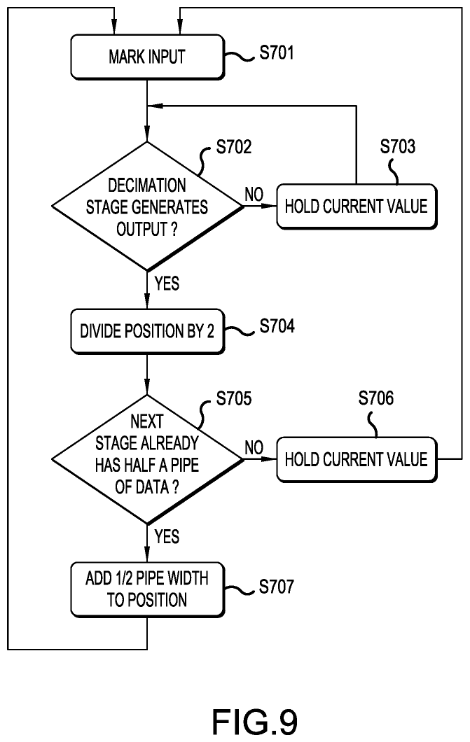

Referring to FIG. 9, a flowchart is provided to describe the process of marking the position of a sample of interest as it propagates through a decimation circuit such as that shown in FIG. 8. The process begins at S701, where the position of the sample of interest is marked. This marked position serves as a reference point that is used to track the sample of interest as it moves through the decimation circuit.

At S702, a determination is made as to whether the given decimation stage has generated an output. If the decimation stage has not generated an output (No at S702), the current marked positional value is held at S703. This means that the marked position remains the same and is not updated until the decimation stage generates an output.

On the other hand, if the decimation stage has generated an output (Yes at S702), the value of the marked position is divided by 2 at S704. This operation effectively reduces the marked position by half, reflecting the fact that the number of samples in the output data pipe is half the number of samples in the input data pipe due to the decimation process.

Next, at S705, a determination is made as to whether the next stage of the decimation circuit is already half filled with data. If the next stage of the decimation circuit is not already half filled with data (No at S705), the currently marked positional value is held at S706.

On the other hand, if the next stage of the decimation circuit is already filled with data, one-half a pipe width is added to the marked position at S707. This operation effectively shifts the marked position by half a pipe width, reflecting the fact that the marked sample has moved to the next half of the data pipe due to the decimation process.

Through this process, the marked sample is tracked through the decimation circuit such that a resolution of the mark position in the output data pipe is the same as a resolution of the mark position in the input data pipe. This ensures that the marked sample can be accurately tracked and located within the output data pipe, regardless of the time resolution.

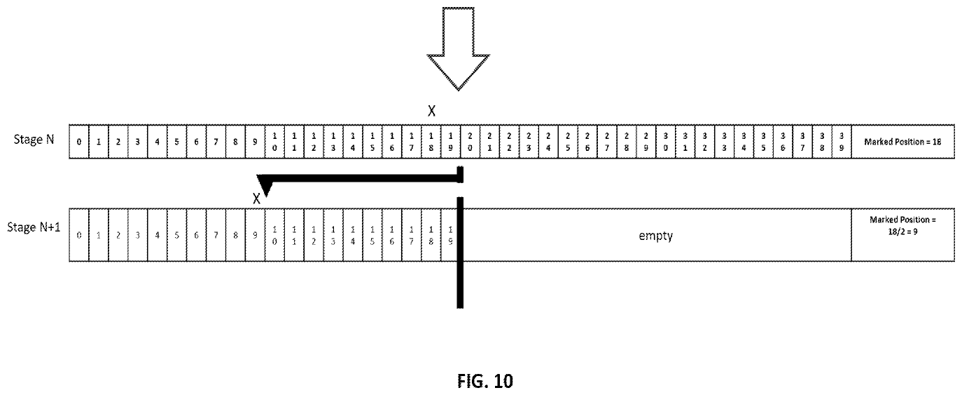

Referring to FIG. 10, an example of the decimation process is illustrated. In this example, the width of the pipe is forty (40) samples. The samples in each pipe are numbered with zero-based indexing, i.e., 0 through 39. At Stage N of the decimation circuit, it is assumed that sample position 18 within the pipe constitutes the marked position. The output of decimation stage N in this example consists of twenty samples as depicted in Stage N+1 of FIG. 10. As dictated by S704 of FIG. 9, the mark position within the pipe is divided by 2. Thus, in this example, the marked position becomes 18/2=9.

In the example of FIG. 10, the next Stage N+1 was not already occupied with a half pipe of data (No at S705 of FIG. 8), and thus the mark position remains at 9 as the pipe is forwarded to the next stage of the decimation circuit. This demonstrates how the marked sample is tracked through the decimation circuit, ensuring that the resolution of the mark position in the output data pipe is the same as the resolution of the mark position in the input data pipe. This process ensures that the marked sample can be accurately tracked and located within the output data pipe, regardless of the decimation process.

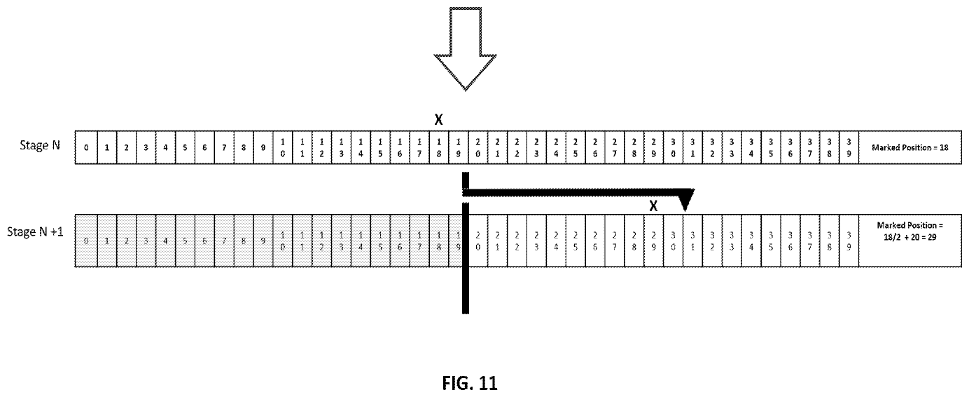

Referring to FIG. 11, an example of the decimation process is illustrated in a scenario where the next Stage N+1 of the decimation circuit is already filled with a half pipe of data (Yes at S705 of FIG. 8). In FIG. 11, the data already occupying the pipe is represented by the shaded sample positions of Stage N+1. This scenario is different from the previous example in FIG. 10, where the next Stage N+1 was not already occupied with a half pipe of data.

In this case, as dictated by S707 of FIG. 8, half a width of the pipe is added to the marked position. This operation effectively shifts the marked position by half a pipe width, reflecting the fact that the marked sample has moved to the next half of the data pipe due to the decimation process. This adjustment is made to ensure that the marked position accurately reflects the location of the marked sample within the output data pipe.

In the example of FIG. 11, the marked position becomes 9+20=29. Again, this demonstrates how the marked sample is tracked through the decimation circuit, ensuring that the resolution of the mark position in the output data pipe is the same as the resolution of the mark position in the input data pipe. This process ensures that the marked sample can be accurately tracked and located within the output data pipe, regardless of the time resolution.

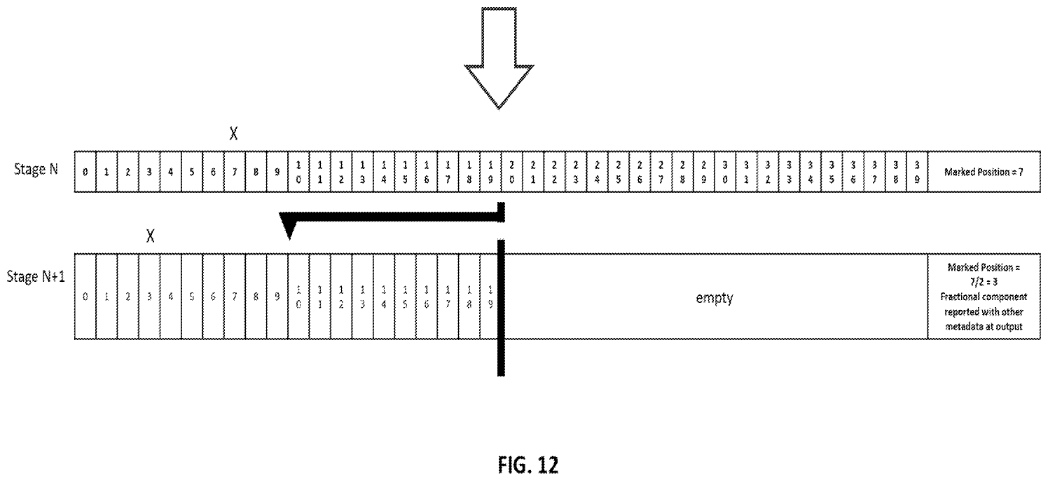

FIG. 12 depicts another example in which an odd-numbered sample within the pipe is indexed. As shown, the input pipe sample 7 is marked. In this case the output mark position is 7/2=3.5. This 0.5 fractional part is preserved in the meta data.

It is worth noting that the process of tracking the marked sample through the decimation circuit is independent of the specific decimation factor used. The marked sample can be accurately tracked and located within the output data pipe, regardless of whether the decimation factor is two, as in the examples shown in FIG. 10 and FIG. 11, or some other value. This flexibility allows the signal processing device to adapt to different signal processing tasks and requirements.

As described above, according to embodiments herein, a specific sample within the input data pipe is marked as a sample of interest. The specific sample has a mark position within the input data pipe. This mark position is a reference point that is used to track the sample of interest as it moves through the system. The marked sample is tracked through the system such that a resolution of the mark position in the output data pipe is the same as the time resolution of the mark position in the input data pipe. This ensures that the marked sample can be accurately tracked and located within the output data pipe, regardless of the decimation process.

In some cases, the mark position may be used to align a trigger when plotting data. This involves using the mark position as a reference in calculation to determine when to start plotting the data. This can be useful for aligning the data with other signals or events, or for synchronizing the data with the operation of other components of the system.

In other cases, the mark position may be used to determine the location of the marked sample within the reduced set of samples output from the decimation circuit. This involves using the mark position as a reference point to identify the marked sample within the output data pipe. This can be useful for tracking the marked sample as it moves through the system, or for identifying the marked sample for further processing or analysis.

It is noted that the digital oscilloscope 100 of FIG. 1 and the spectrum analyzer 500 of FIG. 7 are merely provided as examples of signal processing systems to which the inventive concepts may be applied. As such, the inventive concepts are not limited to these specific examples, and instead can be applied to any signal processing device in which tracking of a sample of interest through a decimation circuit is desired.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. While representative embodiments are disclosed herein, one of ordinary skill in the art will appreciate that many variations that are in accordance with the present teachings are possible and remain within the scope of the appended claim set. The invention therefore is not to be restricted except within the scope of the appended claims.

What is claimed is:

1. A method for tracking a sample of interest in a signal processing device, the method comprising:
receiving a plurality of samples in an input data pipe, wherein the input data pipe comprises a predetermined number of samples;
marking a specific sample within the input data pipe as a sample of interest, the specific sample having a mark position within the input data pipe;
processing the plurality of samples through a decimation circuit, wherein the decimation circuit is configured to output a reduced set of samples in an output data pipe;
tracking the marked sample through the decimation circuit to determine a mark position of the marked sample within the reduced set of samples in the output data pipe; and
outputting the mark position as metadata associated with the reduced set of samples,
wherein the marked sample is tracked through the decimation circuit such that a resolution of the mark position in the output data pipe is the same as a resolution of the mark position in the input data pipe.

2. The method of claim 1, wherein the decimation circuit comprises a plurality of cascaded decimate-by-two stages.

3. The method of claim 2, wherein the decimation circuit is configured to process multiple samples per clock cycle.

4. The method of claim 1, wherein the marked sample is used for triggering in an oscilloscope application.

5. The method of claim 1, wherein the marked sample is used for phase correction in a spectrum analyzer application.

6. The method of claim 1, further comprising using the mark position to align a trigger when plotting data.

7. The method of claim 1, further comprising using the mark position to correct a phase offset introduced during signal acquisition.

8. The method of claim 1, wherein the mark position is used to determine the location of the marked sample within the reduced set of samples output from the decimation circuit.

9. The method of claim 1, wherein the mark position is used to facilitate data compression operations of the signal processing device.

10. The method of claim 1, wherein the mark position is used to facilitate plotting operations of the signal processing device.

11. A signal processing device configured to implement the method of claim 1.

12. The signal processing device of claim 11, wherein the device is an oscilloscope.

13. The signal processing device of claim 11, wherein the device is a spectrum analyzer.

14. The signal processing device of claim 11, wherein the device comprises an Application-Specific Integrated Circuit (ASIC) configured to implement the method of claim 1.

15. The signal processing device of claim 14, wherein the ASIC is configured to process multiple samples per clock cycle through a decimation circuit.
